(19) United States
(12) Patent Application Publication
(10) Pub. No.: US 2018/0190521 A1
(43) Pub. Date: Jul. 5, 2018

(54) SUBSTRATE PROCESSING APPARATUS

(71) Applicant: Tokyo Electron Limited, Tokyo (JP)

(72) Inventor: Hirokazu Ueda, Yamanashi (JP)

(21) Appl. No.: 15/854,047

(22) Filed: Dec. 26, 2017

(30) Foreign Application Priority Data
Jan. 5, 2017 (JP) 2017-000730

(51) Int. Cl. H01L 21/67; H01L 21/687; C23C 16/44; C23C 16/455; H01L 21/677

(52) U.S. Cl. CPC H01L 21/67201; H01L 21/68764; C23C 16/4405; C23C 16/45502; H01L 21/67098; H01L 21/6719; H01L 21/67184; H01L 21/67763; H01L 21/67028

(57) ABSTRACT

Disclosed is a substrate processing apparatus including: n (n is an integer of 4 or more) vacuum processing modules each provided with a vacuum container for processing a substrate in a vacuum atmosphere; and an auxiliary facility group including a processing gas supply facility, an evacuation facility, a chiller facility, and a power supply facility. The n vacuum processing modules are grouped into first and second group sets, and in each group set, the vacuum processing modules included in each group share an auxiliary facility selected from the auxiliary facility group.

### CROSS-REFERENCE TO RELATED APPLICATIONS

This application is based on and claims priority from Japanese Patent Application No. 2017-000730 filed on Jan. 5, 2017 with the Japan Patent Office, the disclosure of which is incorporated herein in its entirety by reference.

### TECHNICAL FIELD

The present disclosure relates to a technique for processing a substrate using a plurality of vacuum processing modules.

### BACKGROUND

In a semiconductor manufacturing process, a vacuum processing (e.g., film formation, etching, ashing, or annealing) is performed on a semiconductor wafer (hereinafter referred to as a “wafer”). In order to perform the vacuum processing at a high throughput, there has been known a substrate processing apparatus called, for example, a multi-chamber system in which a vacuum conveyance chamber having a polygonal shape in a plan view is connected to an equipment front end module (EFEM) via a load lock module, and a vacuum processing module is connected to each side wall surface of the vacuum conveyance chamber.

Meanwhile, recently, due to diversification of semiconductor devices, a vacuum processing requiring a long time until the completion of the processing may be required in some cases. For example, in a case of forming a NAND circuit which is a three-dimensional memory, a plurality of oxide layers and nitride layers are alternately stacked. Thus, a considerably long time is required for one film formation processing. Therefore, in order to increase the throughput, it is demanded to construct a technique for increasing the number of vacuum processing modules provided in the substrate processing apparatus.

Here, the vacuum processing module performs a vacuum processing on a wafer using various auxiliary facilities such as, for example, a processing gas supply facility that supplies a processing gas, an evacuation facility that evacuates a vacuum container in which the wafer is disposed, and a power supply facility that supplies a power to power consuming devices.

In a case where the auxiliary facilities are individually provided for each vacuum processing module provided in the substrate processing apparatus, the number of auxiliary facilities provided increases as the number of vacuum processing modules provided increases, which causes increase in cost of the apparatus. In addition, there is also a concern about increasing the occupied area (footprint) in a clean room where the substrate processing apparatus is provided.

Meanwhile, in a case where the auxiliary facilities are shared by a plurality of vacuum processing modules, when a vacuum processing is to be performed on a wafer in a certain vacuum processing module, various restrictions may occur due to the fact that the auxiliary facilities used in the vacuum processing module are shared by other vacuum processing modules. The various restrictions described here may be desirably removed as much as possible in order to minimize machine differences among a plurality of vacuum processing modules and uniformly control the quality and thickness of the films formed on wafers processed by different vacuum processing modules.

For example, U.S. Pat. No. 8,741,394 (see column 36, line 50 to column 39, line 31, FIGS. 38 and 39) discloses a technique of distributing raw material gases supplied from common raw gas supply sources (manifolds) to four processing stations (corresponding to vacuum processing modules) via a common mixing container, and switching valves provided on a flow path to switch the supply source of the raw material gases, in forming a laminated structure of thin films by plasma CVD.

However, the '394 patent does not mention restrictions caused by sharing a raw gas supply source (corresponding to the processing gas supply facility) to four processing stations.

### SUMMARY

An aspect of the present disclosure provides a substrate processing apparatus including: n (n is an integer of 4 or more) vacuum processing modules each provided with a vacuum container for processing a substrate in a vacuum atmosphere; and an auxiliary facility group including a processing gas supply facility that supplies a processing gas into the vacuum container, an evacuation facility that evacuates the vacuum container, a chiller facility that controls a temperature of the vacuum container, and a power supply facility that supplies a power to power consuming devices provided in the vacuum processing modules. The n vacuum processing modules are grouped into a first group set including a plurality of groups each including a combination of 2 to (n−2) vacuum processing modules, and the vacuum processing modules included in each group share at least one first auxiliary facility selected from the auxiliary facility group, and the n vacuum processing modules are grouped into a second group set including a plurality of groups each including a combination of 2 to (n−2) vacuum processing modules in which at least one vacuum processing module is different from the combination of vacuum processing modules included in each group of the first group set, and the vacuum processing modules included in each group share at least one second auxiliary facility selected from the auxiliary facility group and different from the first auxiliary facility.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a horizontal sectional plan view of a substrate processing apparatus according to an embodiment of the present disclosure.

FIG. 2 is a perspective view illustrating the external appearance of a stacked block of processing units provided in the substrate processing apparatus.

FIG. 3 is a schematic diagram illustrating an installation state of auxiliary facilities to processing units according to a comparative embodiment.

FIG. 4 is an explanatory view illustrating a wafer processing procedure by the substrate processing apparatus according to the comparative embodiment.

FIG. 5 is a horizontal sectional plan view illustrating an arrangement example of processing units and auxiliary facilities according to the embodiment.

FIG. 6 is a schematic diagram illustrating an installation state of auxiliary facilities to the processing units.

FIG. 7 is an explanatory view illustrating a wafer processing procedure by the substrate processing apparatus according to the embodiment.

FIG. 8 is a horizontal sectional plan view illustrating another arrangement example of the processing units and auxiliary facilities.

FIG. 9 is a schematic diagram illustrating an installation state of auxiliary facilities to processing units according to a second embodiment.

FIG. 10 is an explanatory diagram summarizing process conditions that may be set for each vacuum processing module.

FIGS. 11A and 11B are explanatory diagrams summarizing process conditions that may be set for each vacuum processing module in other embodiments.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made under the foregoing circumstances, and an object of the present disclosure is to provide a substrate processing apparatus capable of reducing restrictions occurring in processing a substrate by using a plurality of vacuum processing modules while sharing auxiliary facilities in the respective vacuum processing modules.

An aspect of the present disclosure provides a substrate processing apparatus including: n (n is an integer of 4 or more) vacuum processing modules each provided with a vacuum container for processing a substrate in a vacuum atmosphere; and an auxiliary facility group including a processing gas supply facility that supplies a processing gas into the vacuum container, an evacuation facility that evacuates the vacuum container, a chiller facility that controls a temperature of the vacuum container, and a power supply facility that supplies a power to power consuming devices provided in the vacuum processing modules. The n vacuum processing modules are grouped into a first group set including a plurality of groups each including a combination of 2 to (n−2) vacuum processing modules, and the vacuum processing modules included in each group share at least one first auxiliary facility selected from the auxiliary facility group, and the n vacuum processing modules are grouped into a second group set including a plurality of groups each including a combination of 2 to (n−2) vacuum processing modules in which at least one vacuum processing module is different from the combination of vacuum processing modules included in each group of the first group set, and the vacuum processing modules included in each group share at least one second auxiliary facility selected from the auxiliary facility group and different from the first auxiliary facility.

The above-described substrate processing apparatus further includes a substrate conveyance section provided with a first substrate conveyance mechanism that conveys the substrate under a normal pressure atmosphere. The n vacuum processing modules are separately provided in a plurality of processing units each including first and second vacuum processing modules, and a load lock module that is connected to each of the vacuum containers of the first and second vacuum processing modules and provided with a second substrate conveyance mechanism that conveys the substrate between the substrate conveyance section and each of the vacuum containers in a load lock chamber configured to freely switch an internal atmosphere between a normal pressure atmosphere and a vacuum atmosphere, and the first auxiliary facility includes a gas supply facility, and the first and second vacuum processing modules in each of the processing units are grouped into different groups in the first group set.

In the above-described substrate processing apparatus, the plurality of processing units are stacked vertically in multiple tiers to form a plurality of stacked blocks, and for each of the plurality of stacked blocks, the first vacuum processing modules included in one stacked block are grouped into a common group, and the second vacuum processing modules included in the stacked block are grouped into a common group different from the group including the first vacuum processing modules.

In the above-described substrate processing apparatus, the first and second vacuum processing modules in each of the processing units are arranged side by side in a lateral (left and right) direction when viewed from the load lock module side, the first vacuum processing modules are evenly stacked vertically in multiple tiers on one side of the left and right sides, and the second vacuum processing modules are evenly stacked vertically in multiple tiers on the other side of the left and right sides, the substrate conveyance section is constituted by disposing the first substrate conveyance mechanism in an elongated planar substrate conveyance chamber, and on both sides of the substrate conveyance section, the plurality of stacked blocks are arranged side by side along a longer side direction of the elongated substrate conveyance chamber, and for two stacked blocks adjacent to each other along the substrate conveyance chamber or two stacked blocks facing each other across the substrate conveyance chamber, first vacuum processing modules of one stacked block and second vacuum processing modules of the other stacked block are grouped into a common group.

In the above-described substrate processing apparatus, when facilities remaining unselected as the first and second auxiliary facilities remain in the auxiliary facility group, the n vacuum processing modules are further grouped into an i^{th} group set including a plurality of groups each including a combination of 2 to (n−2) vacuum processing modules in which at least one vacuum processing module is different from the combination of vacuum processing modules included in each group of the first to (i−1)^{th} group sets, and the vacuum processing modules included in each group share at least one i^{th} auxiliary facility selected from the auxiliary facility group and different from the first to (i−1)^{th} auxiliary facilities (i is an integer of 3 to a value obtained by adding to a value of (i−1) a number of facilities in the auxiliary facility group which are not selected up to the (i−1)^{th} group set).

In the above-described substrate processing apparatus, the processing gas supply facility includes a processing gas adjustment unit that performs at least one of adjustment of execution timing of supply of a processing gas into the vacuum container or stop of the supply and adjustment of supply flow rate of the processing gas, the evacuation facility includes a pressure adjustment unit that adjusts a pressure in the vacuum container, the power supply facility includes a power supply unit that adjusts a power to be supplied to at least one of a plasma generation unit configured to convert the processing gas supplied into the vacuum container into plasma and a heating unit configured to heat the substrate disposed in the vacuum container, and the chiller facility includes a temperature adjustment unit that adjusts at least one of a temperature and a flow rate of a coolant to be supplied to a coolant flow path formed in the vacuum container or a placing table of the substrate.

The above-described substrate processing apparatus further includes a controller that sets a target value of each adjustment unit provided in the auxiliary facilities such that results of the processing on the substrate become uniform among vacuum processing modules having different combinations of shared auxiliary facilities.

In the present disclosure, a plurality of vacuum processing modules provided in a substrate processing apparatus are distributed into a plurality of group sets (first and second group sets) which are grouped differently from each other, so that different types of auxiliary facilities are shared in each group included in each group set. Thus, it is possible to reduce occurrence of restrictions caused by sharing all auxiliary facilities among the vacuum processing modules in the same group.

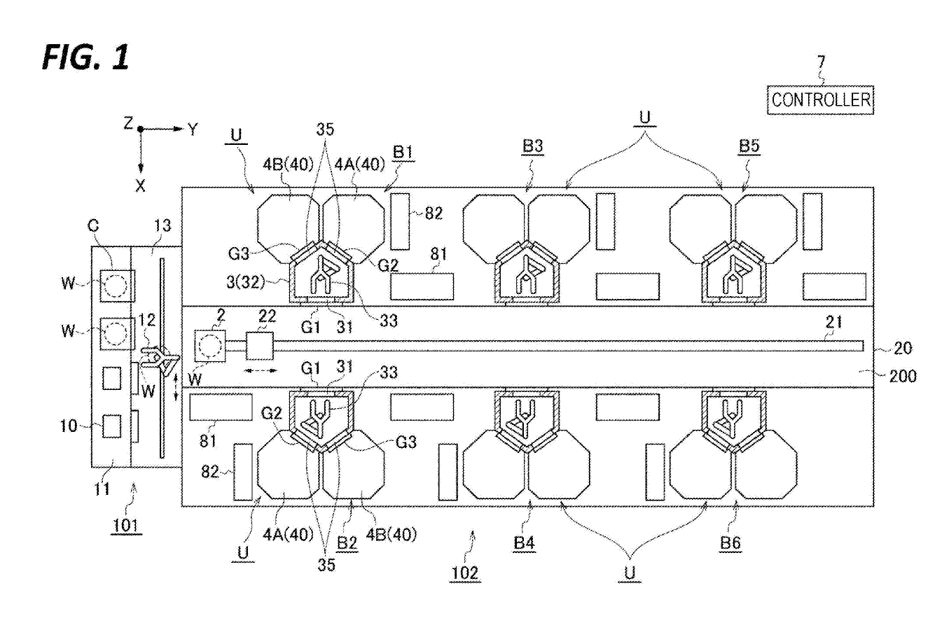

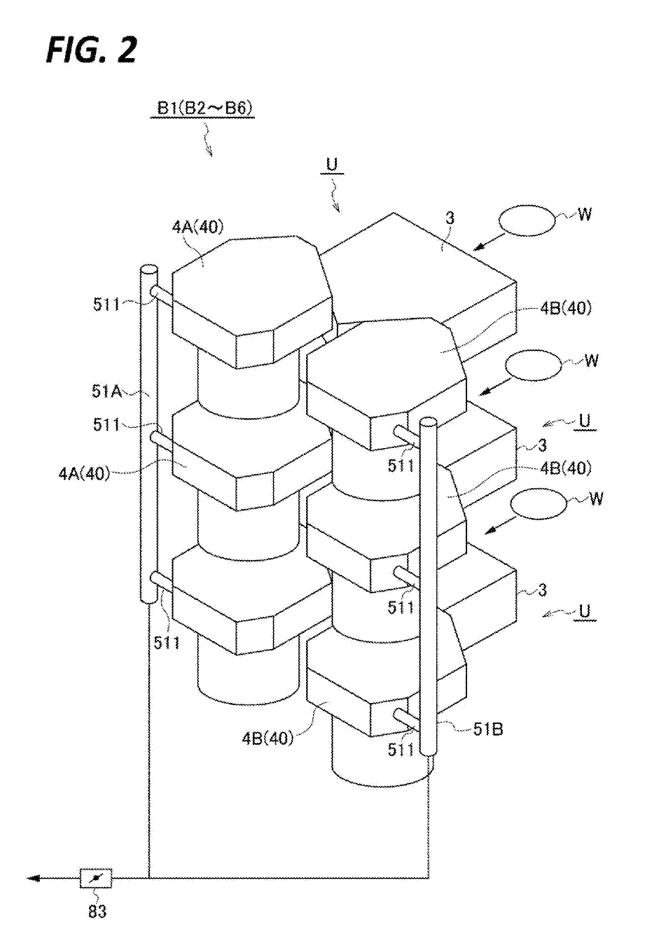

First, the configuration of a substrate processing apparatus according to an embodiment of the present disclosure will be described with reference to FIGS. 1 and 2. As illustrated in the horizontal sectional plan view of FIG. 1, the substrate processing apparatus of the present example includes an EFEM 101 configured to take out wafers W from a carrier C which is a conveyance container accommodating a plurality of wafers W and a processing block 102 connected to the EFEM 101 and configured to perform a processing on the wafer.

For example, the EFEM 101 includes a load port 11 which is a container placement section configured such that four carriers C serving as front opening unified pods (FOUPs) are placed, for example, in the left and right direction (X direction in FIG. 1) when viewed from the front side. A support portion 10 is provided on the placement surface of the carrier C in the load port 11 to support the bottom surface of the carrier C in a positioned state. A conveyance chamber 13 is provided behind the load port 11 and includes a conveyance mechanism 12 that delivers wafers to and from the carrier C.

The processing block 102 includes a substrate conveyance section 20 that conveys the wafer W delivered from the EFEM 101 side and a plurality of stacked blocks B1 to B6 in which a plurality of processing units U connected to the substrate conveyance section 20 are stacked in multiple tiers in the vertical direction. The substrate conveying unit 20 and the stacked blocks B1 to B6 are accommodated in a housing (not illustrated).

The substrate conveyance section 20 includes a substrate conveyance chamber 200 extending in an elongated planar shape in the front and rear direction when viewed from the EFEM 101 side. The substrate conveyance chamber 200 has a height that enables each processing unit U (more specifically, a load lock module 3 in the processing unit U) constituting the stacked blocks B1 to B6 to be connected to the substrate conveyance chamber 200. A fan filter unit (not illustrated) is provided on the upper surface side of the substrate conveyance chamber 200, and the interior of the substrate conveyance chamber 200 is configured as a space of, for example, a normal-pressure clean air atmosphere.

A traveling rail 21, which is a moving path extending along the front and rear direction, is provided in the bottom portion of the substrate conveyance chamber 200. A support unit 22 is provided in the substrate conveyance chamber 200 to be movable in the front and rear direction while being guided by the traveling rail 21, and a first substrate conveyance mechanism 2 is provided on a lateral surface of the support unit 22 on the EFEM 101 side to be liftable along the support unit 22.

In the present example, the first substrate conveyance mechanism 2 has a structure in which wafer holding units (not illustrated) for holding wafers W one by one are provided in multiple tiers, for example, in a housing with the front face opened. Further, the first substrate conveyance mechanism 2 is supported by the support unit 22 via a rotation driving unit (not illustrated) that rotates the housing around a vertical axis. With this configuration, the first substrate conveyance mechanism 2 may direct the opening face of the housings to the EFEM 101 side and the left and right sides of the substrate conveyance chamber 200 provided with the stacked blocks B1 to B6.

It is not indispensable to constitute the first substrate conveyance mechanism 2 by a housing capable of accommodating wafers W in multiple tires. For example, one or more articulated arms which may be expandable/contractible and rotatable may be provided to be movable along the traveling rail 21 and liftable along the support unit 22. In this case, a shelf-like wafer placement unit may be provided between the EFEM 101 and the substrate conveyance section 20 to temporarily place a wafer W to be conveyed.

On each of the left and right sides of the substrate conveyance section 20 as viewed from the EFEM 101 side, for example, a plurality of (three in the present example) stacked blocks B1 to B6, each of which has three processing units U stacked in the vertical direction, are arranged.

For example, each of the stacked blocks B1 to B6 has an accommodation frame (not illustrated) in which accommodation spaces capable of accommodating the processing units U are arranged in a shelf-like form in the vertical direction, and each processing unit U is stacked in the vertical direction by being accommodated in each accommodation space.

Descriptions will be made on the configuration of the processing units U provided in the stacked blocks B1 to B6. Each processing unit U includes a load lock module (LLM) 3 and a plurality of, for example, two vacuum processing modules (e.g., first and second vacuum processing module 4A and 4B) that deliver wafers W to and from the first substrate conveyance mechanism 2 via the LLM 3.

As illustrated in FIGS. 1 and 2, the LLM 3 has, for example, a structure in which a second substrate conveyance mechanism 33 is provided in a load lock chamber 32 having a pentagonal planar shape. On one lateral surface of the load lock chamber 32, a carry-in/out port 31 is provided to be opened and closed by a gate valve G1 and performs a carry-in/out of the wafer W. Each processing unit U is connected to the substrate conveyance section 20 with the carry-in/out port 31 facing the side wall surface of the substrate conveyance chamber 200.

Meanwhile, a carry-in/out port 35 capable of being opened and closed by gate valves G2 and G3 is provided on each of the two surfaces located on the rear side of the load lock chamber 32 when viewed from the connection surface with the substrate conveyance section 20. And, a vacuum container 40 constituting the first and second vacuum processing modules 4A and 4B is airtightly connected to the side wall surface of the substrate conveyance section 20 provided with the carry-in/out port 35. That is, the first and second vacuum processing modules 4A and 4B are arranged side by side in the lateral (left and right) direction when viewed from the LLM 3 (or the substrate conveyance section 20) side. In the processing unit U of the present example, the right one when viewed from the LLM 3 side is regarded as the first vacuum processing module 4A, and the left one is regarded as the second vacuum processing module 4B.

The load lock chamber 32 is connected with an exhaust pipe (not illustrated). Thus, the internal atmosphere may be switched between an atmospheric pressure (normal pressure atmosphere) and a vacuum atmosphere by evacuating the interior of the load lock chamber 32 via the exhaust pipe.

The second substrate conveyance mechanism 33 provided in the load lock chamber 32 is constituted by, for example, an articulated arm that is expandable/contractible and rotatable around the vertical axis, and performs a delivery of the wafer W between the first substrate conveyance mechanism 33 which has moved to the front of the connection position of the LLM 3, and the first and second vacuum processing modules 4A and 4B.

In the vacuum container 40 constituting the first and second vacuum processing modules 4A and 4B, for example, film formation, which is a vacuum processing, is performed on the wafer W. The vacuum container 40 includes, for example, a placing table on which a wafer W to be processed is placed and which has a heating unit for heating the wafer W, a gas shower head that supplies a processing gas for film formation or a cleaning gas for cleaning the inside of the vacuum container 40 into the vacuum container 40, and a plasma generation unit that converts the processing gas into plasma when film formation is performed using plasma (all not illustrated).

On the lower side of the vacuum container 40, for example, a driving mechanism that drives the second substrate conveyance mechanism 33 in the LLM 3, a placing table provided in the vacuum container 40 of each of the first and second vacuum processing modules 4A and 4B, and a delivery mechanism that delivers wafers W to and from the second substrate conveyance mechanism 33 on the LLM 3 side, are provided, but illustration and description thereof will be omitted.

As illustrated in FIGS. 1 and 2, the processing units U having the above-described configuration are stacked in multiple tiers (three tiers in the present example) in the vertical direction to constitute the stacked blocks B1 to B6, such that the LLM 3 of each processing unit U is connected to the substrate conveyance section 20. As a result, in the substrate processing apparatus of the present example, a total of 18 processing units U constituting the six stacked blocks B1 to B6 are connected to the substrate conveyance section 20, so that film formation may be performed on the wafers W using 36 vacuum processing modules 4A and 4B.

In other words, in the substrate processing apparatus of the present example, it may be considered that 36 (n=36) vacuum processing modules 4A and 4B are provided separately in 18 processing units U.

In the substrate processing apparatus having the above-described configuration includes a gas box 81 which is a processing gas supply facility for supplying a processing gas for film formation to the vacuum containers 40 of the respective vacuum processing modules 4A and 4B, exhaust pipes MA and MB and an automatic pressure control (APC) valve 83 constituting an evacuation facility for evacuating the vacuum container 40, and a power supply box 82 which is a power supply facility for supplying a power to power consuming devices such as, for example, a plasma generation unit provided in the vacuum processing modules 4A and 4B, a heating unit of the wafer W, and various driving devices.

The gas box 81, the APC valve 83, and the power supply box 82, which are auxiliary facilities, constitute an auxiliary facility group of the embodiment.

As illustrated in FIG. 1, gas boxes 81 are provided, for example, on the left side when viewed from the stacked blocks B1 to B6 facing the substrate conveyance section 20. The gas boxes 81 may supply various processing gases for film formation to the vacuum container 40 provided in each of the vacuum processing modules 4A and 4B, as well as, for example, a purge gas for discharging an unnecessary processing gas.

On the rear side of each gas box 81 when viewed from the substrate conveyance section 20 side, a power supply box 82 is provided to supply a power to the various power consuming devices provided in the LLM 3 and the vacuum processing modules 4A and 4B.

Further, as illustrated in FIG. 2, each of the stacked blocks B1 to B6 is provided with a first exhaust pipe 51A for evacuating the vacuum container 40 on the first vacuum processing module 4A side stacked in multiple tiers in the vertical direction, and a second exhaust pipe 51B for evacuating the vacuum container 40 on the second vacuum processing module 4B side. For example, the exhaust pipes 51A and 51B are disposed at the left and right side positions on the outer side of the vacuum processing modules 4A and 4B, respectively, when viewed from the processing unit U so as to extend in the vertical direction along the stacking direction of the processing units U.

A branch pipe 511 branches from each exhaust pipe 51A and 51B at the arrangement height position of each vacuum container 40, and the vacuum container 40 and the exhaust pipes 51A and 51B are connected via these branch pipes 511.

The two exhaust pipes 51A and 51B merge at the downstream side, and are connected to an evacuation line for factory power via the APC valve 83 which is a pressure adjustment unit for adjusting the pressure inside each vacuum vessel 40, at further downstream side of the merging position. The first and second exhaust pipes 51A and 51B, the branch pipe 511, and the APC valve 83 constitute the evacuation facility of the present example.

With the above-described configuration, the first exhaust pipe 51A is commonly connected to the vacuum containers 40 of the first vacuum processing modules 4A stacked in multiple tiers (three tiers in the present example) in the vertical direction within each of the stacked blocks B1 to B6. In addition, the second exhaust pipe 51B is commonly connected to the vacuum containers 40 of the second vacuum processing modules 4B stacked in multiple tiers in the same manner.

Further, the substrate processing apparatus includes a controller 7. For example, the controller 7 is constituted by a computer having a central processing unit (CPU) (not illustrated) and a storage unit, and the storage unit stores a program organized with a step (instruction) group for a control of a content of film formation performed by the first and second vacuum processing modules 4A and 4B of each processing unit U, or a conveyance order of the wafers W by the first substrate conveyance mechanism 2. The program is stored in a storage medium such as, for example, a hard disk, a compact disk, a magnet optical disk, or a memory card, and is installed in the computer therefrom.

In the substrate processing apparatus having the above-described configuration, a plurality of (36 in the present example) vacuum processing modules 4A and 4 provided in the substrate processing apparatus are distributed into a plurality of different group sets (first and second group sets), and different kinds of auxiliary facilities (e.g., the gas box 81, the APC valve 83, and the power supply box 82) are provided in common for each group included in each group set.

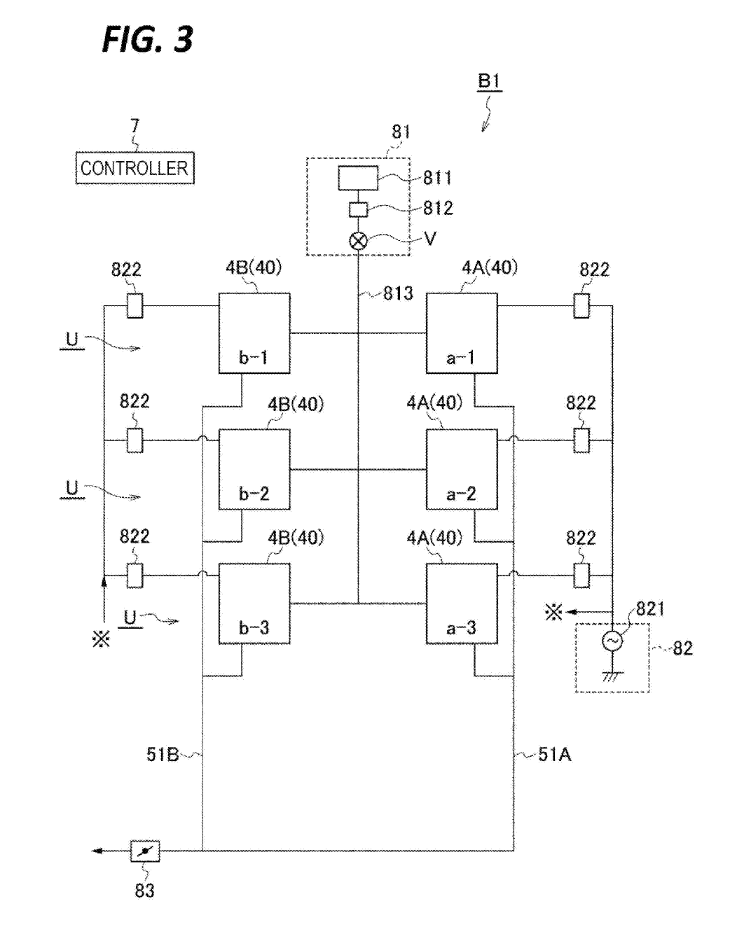

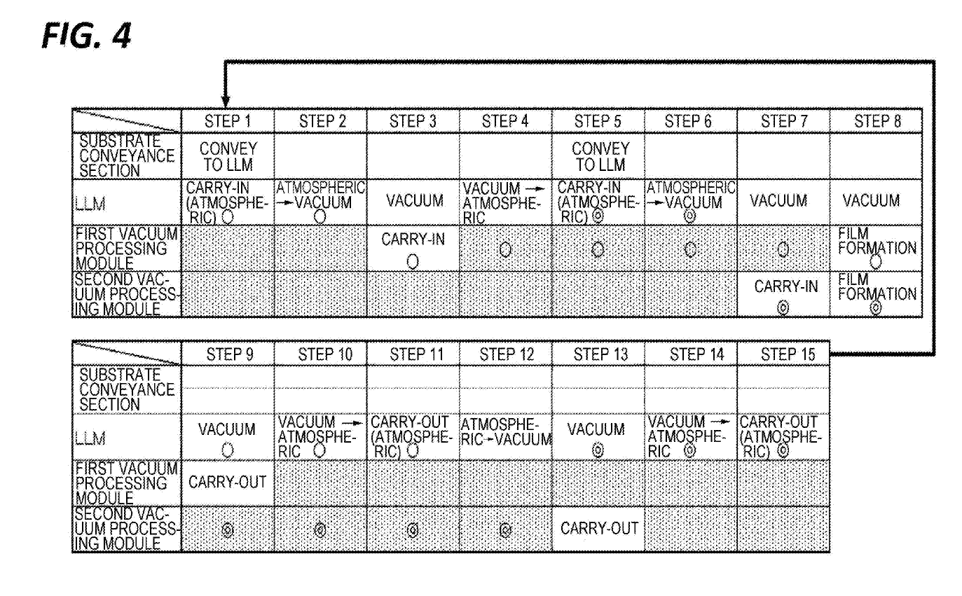

Here, before describing the specific installation state of the auxiliary facilities in the substrate processing apparatus according to the embodiment, descriptions will be made on the installation state of the auxiliary facilities in a comparative embodiment and problems caused by the installation state with reference to FIGS. 3 and 4.

The substrate processing apparatus according to the comparative embodiment is configured in the same manner as the substrate processing apparatus described with reference to FIGS. 1 and 2, except that the installation state of the auxiliary facilities for each of the vacuum processing modules 4A and 4B is different. In FIG. 3, components common to those of the substrate processing apparatus according to the embodiment described with reference to FIGS. 1 and 2 are denoted by the same reference numerals as used in these figures.

The schematic view of FIG. 3 illustrates an installation state of the vacuum processing modules 4A and 4B, for example, for three processing units U constituting the stacked block B1 arranged on the foremost right side when viewed from the EFEM 101 of the substrate processing apparatus illustrated in FIG. 1.

As described above, in each of the stacked blocks B1 to B6, the first vacuum processing module 4A is disposed on the right side when viewed from the LLM 3, and similarly, the second vacuum processing module 4B is disposed on the left side. Therefore, in the stacked blocks B1 to B6, the first vacuum processing modules 4A of the three processing units U are evenly stacked in multiple tiers in the vertical direction on the right side (one side) when viewed from the LLM 3. In addition, the second vacuum processing modules 4B are evenly stacked in multiple tiers in the vertical direction on the left side (the other side) when viewed from the LLM 3.

In the following descriptions, in order to identify each of the vacuum processing modules 4A and 4B, the vacuum processing modules 4A of the stacked block B1 are denoted by identification codes of “a-1, a-2, a-3” sequentially from the upper tier side, and the vacuum processing modules 4B are denoted by identification codes of “b-1, b-2, b-3” sequentially from the upper tier side.

In the substrate processing apparatus according to the comparative embodiment, the gas box 81, the power supply box 82, and the APC valve 83, which are auxiliary facilities, are shared for every six vacuum processing modules 4A and 4B in each of the stacked blocks B1 to B6.

For example, the gas box 81 is provided with a gas supply source 811 for a processing gas for film formation used for film formation. The gas supply source 811 may have any configuration, for example, a configuration in which a solid raw material or a liquid raw material is vaporized into a carrier gas to obtain a processing gas or a configuration in which a raw material gas is supplied directly from a cylinder containing a raw material in a liquid or compressed gas state.

On the outlet side of the gas supply source 811, a mass flow controller (MFC) 812, which is a processing gas adjustment unit for adjusting the supply flow rate of the processing gas for film formation to be supplied to the vacuum container 40 of each of the vacuum processing modules 4A and 4B, and an opening/closing valve V, which is a processing gas adjustment unit for adjusting the execution timing of the supply of the processing gas or the stop of the supply, are provided. The conductance of a raw gas supply line 813 from the MFC 812 to each vacuum container 40 is adjusted so as to be substantially equal to each other between the vacuum processing modules 4A and 4B. Therefore, when the opening/closing valve V is opened, the processing gas whose flow rate has been adjusted by the MFC 812 is divided into approximately six equal parts and supplied to the vacuum containers 40 denoted by the codes “a-1 to a-3, b-1 to b-3.”

A manual opening/closing valve used for the purpose of, for example, maintenance may be provided on the inlet/outlet side of each vacuum container 40.

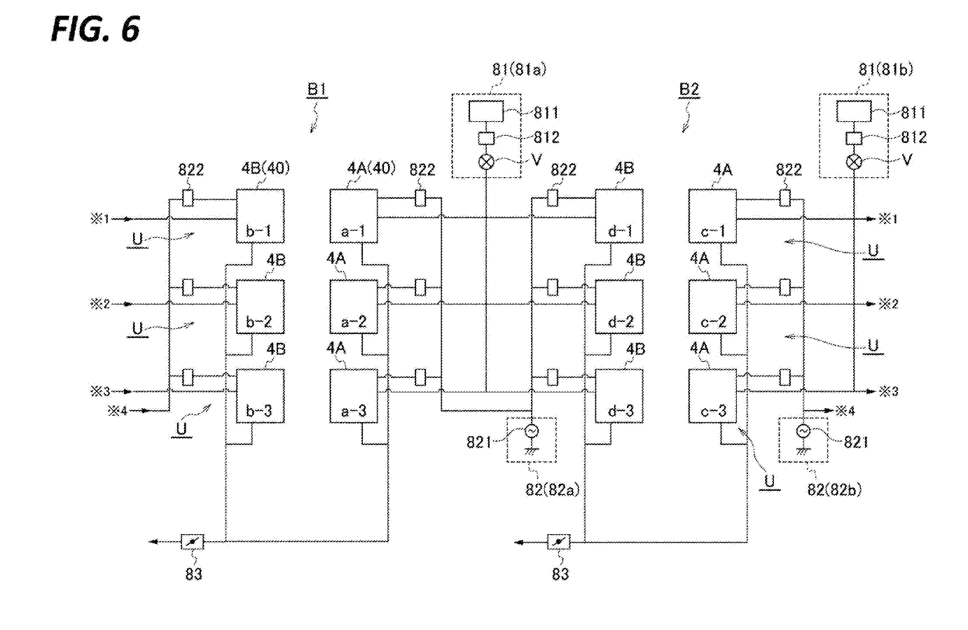

The gas box 81 has a set of the above-described gas supply source 811, MFC 812, and opening/closing valve V for each type of processing gases supplied to each vacuum container 40 at the time of film formation, and supplies each processing gas to each vacuum container 40 via a common raw gas supply line 813 or a raw gas supply line 813 individually provided for each kind of processing gases. For convenience of illustration, in FIGS. 3 and 6, a plurality of sets of gas supply sources 811, MFCs 812, opening/closing valves V, and raw gas supply lines 813 for each type of processing gases are collectively illustrated in one set.

The power supply box 82 includes a power supply unit 821 and is connected to power consuming devices in the respective vacuum processing modules 4A and 4B via a power supply line provided with a matching unit 822 as required (see FIGS. 3 and 6 which illustrate an example of the power supply unit 821 that supplies a high-frequency power to power consuming devices in the vacuum processing modules 4A and 4B via the matching unit 822).

Among the power supply units 821 provided in the power supply boxes 82, the power supply unit 821 for supplying the high-frequency power to the plasma generation units of the vacuum processing modules 4A and 4B has a function as a power supply adjustment unit capable of adjusting the supply power. The plasma generating units of the respective vacuum processing modules 4A and 4B are connected in parallel to the power supply unit 821, and the impedances of the plasma generating units during the period when the processing gas is converted into plasma are adjusted so as to be substantially equal to each other between the vacuum processing modules 4A and 4B.

With the above-described configuration, when a high-frequency power of a preset voltage is applied from the power supply unit 821, in each vacuum container 40, the processing gas for film formation supplied from the gas box 81 is converted into plasma under substantially common conditions.

The plasma generation unit is not limited to a specific configuration. Plasma may be generated by microwaves, or inductively coupled plasma (ICP) may be used in which an eddy current may be generated by a high frequency change magnetic field formed around an antenna to convert the processing gas into plasma. In addition, a parallel plate type plasma generation unit for applying a high-frequency power may be provided between the placing table on which the wafer W is placed and the gas shower head.

Besides, for example, in a case where a heating unit formed of a resistance heating element is provided on the placing table on which the wafer W is placed, the power supply unit 821 for supplying a DC power to the heating section also has a function as a power supply adjustment unit (not illustrated in FIGS. 3 and 6). The heating units of the respective vacuum processing modules 4A and 4B are connected in parallel to the power supply unit 821, and the resistances of the resistance heating elements are adjusted so as to be substantially equal to each other between the vacuum processing modules 4A and 4B.

With the above-described configuration, when a DC power of a preset voltage is applied from the power supply unit 821, the heating units of the respective vacuum processing modules 4A and 4B rise to a preset temperature and heat the wafers W. At this time, a temperature detection unit may be provided to measure the temperature of the wafer W accommodated in any one of the vacuum containers 40, and the DC power supplied from the power supply unit 821 may be increased or decreased based on the detection result of the temperature of the wafer W. Further, the DC power supplied from the power supply unit 821 may be increased or decreased on the basis of the average value of detection results of temperatures of a plurality of wafers W.

Since the installation state of the first and second exhaust pipes 51A and 51B which are vacuum evacuation facilities has been described with reference to FIG. 2, the description thereof will be omitted. However, the APC valve 83 that adjusts the pressure of each vacuum container 40 is shared for every six vacuum processing modules 4A and 4B.

FIG. 3 illustrates an example of the stacked block B1, but in each of the other stacked blocks B2 to B6, similarly to the case of the stacked block B1, the gas box 81, the power supply box 82, and the APC valve 83 are provided in common for the six vacuum processing modules 4A and 4B.

In other words, the 36 vacuum processing modules 4A and 4B provided in the substrate processing apparatus according to the comparative embodiment are grouped in units of stacked blocks B1 to B6, and each of the vacuum processing modules 4A and 4B in each of the stacked blocks B1 to B6 is configured to perform a processing of the wafer W using common auxiliary facilities (e.g., the gas box 81, the power supply box 82, and the APC valve 83).

Descriptions will be made on an operation in the case where a wafer W is processed using the substrate processing apparatus according to the comparative embodiment having the above-described configuration.

First, when the carrier C accommodating wafers W to be processed is placed on the load port 11 of the EFEM 101, the conveyance mechanism 12 takes out the wafers W from the carrier C and conveys the wafers W to the first substrate conveyance mechanism 2. When a preset number of wafers W to be processed are accommodated in the first substrate conveyance mechanism 2, the first substrate conveyance mechanism 2 is moved to the arrangement position of the stacked blocks B1 to B6 in which the processing units U for performing film formation on these wafers W are accommodated. Hereinafter, in the present example, descriptions will be made on a case where a wafer W is carried into each processing unit U of the stacked block B1 illustrated in FIG. 3.

The first substrate conveyance mechanism 2 which has reached the arrangement position of the stacked block B1 directs the opening surface of the housing accommodating the wafer W toward the processing unit U side and aligns the height position of the wafer W to be taken out to a position where the second substrate conveyance mechanism 33 in the LLM 3 of the carry-in destination can enter (step 1 of FIG. 4).

Meanwhile, on the processing unit U side, the gate valve G1 on the substrate conveyance section 20 side is opened in a state where the load lock chamber 32 is in a normal pressure atmosphere. Then, the joint arm of the second substrate conveyance mechanism 33 is extended to enter the first substrate conveyance mechanism 2, and the fork of the joint arm is positioned below the receiving wafer W. Thereafter, as the first substrate conveyance mechanism 2 slightly moves down, the wafer W is received from the holding member in the first substrate conveyance mechanism 2 to the fork.

Upon receiving the wafer W, the second substrate conveyance mechanism 33 retracts the joint arm and carries the wafer W into the LLM 3 (step 1 in FIG. 4). When the gate valve G1 is closed to hermetically seal the LLM 3, the interior of the load lock chamber 32 is switched to a vacuum atmosphere (step 2 in FIG. 4). Next, for example, the gate valve G2 of the vacuum container 40 (a-1 in FIG. 3) on the first vacuum processing module 4A side is opened, and the wafer W is carried into the vacuum container 40 (step 3 in FIG. 4).

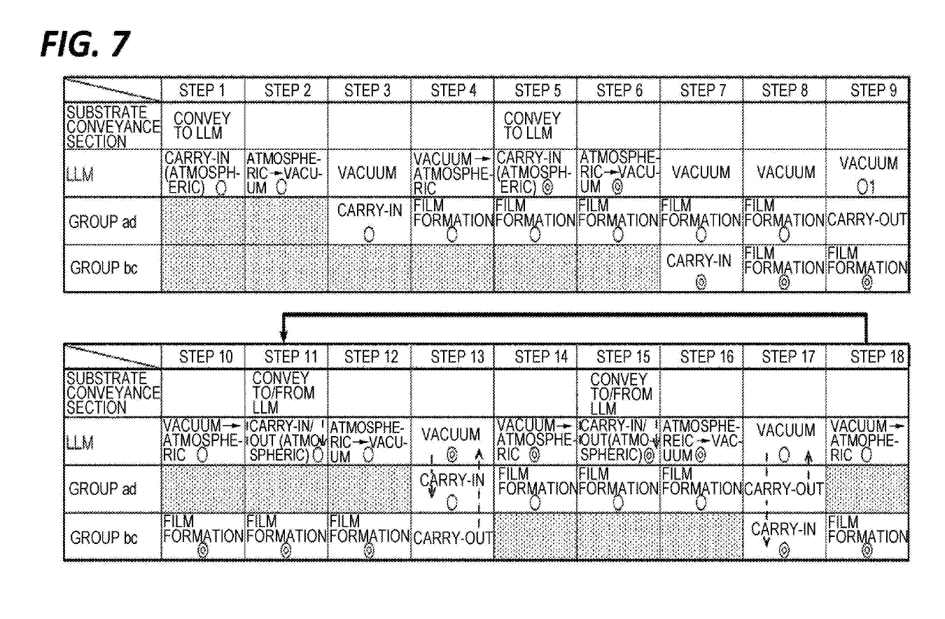

The operations of steps 1 to 3 as described above are performed on the processing units U of the respective tiers of the stacked block B1 and the wafers W are disposed in the vacuum containers 40 of “a-1 to a-3” which are the first vacuum processing modules 4A. In FIG. 4, the wafer W to be processed on the first vacuum processing module 4A side is indicated by a single circle (the same is applied in FIG. 7 to be described later).

In each processing unit U, when the wafer W is carried into the vacuum container 40 of the first vacuum processing module 4A, the interior of the LLM 3 is returned to the normal pressure atmosphere (step 4 in FIG. 4). Then, the wafer W, which is carried into the vacuum container 40 of the second vacuum processing module 4B, is received again from the first substrate conveyance mechanism 2 which has moved to the height position facing the LLM 3, and carried into the LLM 3. In FIG. 4, the wafer W to be processed on the second vacuum processing module 4B side is indicated by a double circle (the same is applied in FIG. 7 to be described later).

Then, vacuum evacuation in the load lock chamber 32 (step 6 in FIG. 4) and carry-in of the wafers W to the vacuum container 40 on the second vacuum processing module 4B side (step 7 in FIG. 4) are performed in the same procedure as in the case of the first vacuum processing module 4A side, and the wafers W are disposed in the vacuum containers 40 of “b-1 to b-3.”

After the wafers W are disposed in the vacuum containers 40 of all the vacuum processing modules 4A and 4 B in the stacked block B1, a DC power is supplied from the power supply box 82 to the heating unit in each vacuum container 40 to heat the wafer W to a preset temperature. Then, based on a preset sequence, one or more types of processing gases for film formation are supplied from the gas box 81 into each vacuum container 40 in a predetermined order and at a flow rate. In the case of converting the processing gas into a plasma by using the plasma generation unit, a high-frequency power is applied to the plasma generation unit of each vacuum container 40 from the power supply box 82 to convert the processing gas into plasma, thereby performing film formation (step 8 in FIG. 4). In addition, during the period, the pressure in each vacuum container 40 is adjusted by the APC valve 83 so as to be maintained at a preset pressure.

Then, when the preset operation related to the film formation (e.g., supply and switching of the processing gases, or conversion of the processing gases into plasma, and heating of the wafers W) is performed, for example, the wafers W are delivered from the vacuum containers 40 of “a-1 to a-3” that are the first vacuum processing modules 4A to the first substrate conveyance mechanism 2 in the procedure opposite to that at the time of the carry-in of the wafers W (steps 9 to 11 in FIG. 4). Next, after the interior of the load lock chamber 32 is evacuated again (step 12 in FIG. 4), the wafers W are delivered from the vacuum containers 40 of “b-1 to b-3” that are the second vacuum processing module 4B to the first substrate conveyance mechanism 2 (steps 13 to 15 in FIG. 4).

In this manner, the film-formed wafers W are taken out from all the vacuum processing modules 4A and 4B in the stacked block B1, and when a predetermined number of the film-formed wafers W are accommodated in the first substrate conveyance mechanism 2, the first substrate conveyance mechanism 2 is moved to the EFEM 101 side and the film-formed wafer W is returned to the original carrier C in a procedure opposite to that at the time of the carry-in.

Further, on the side of the stacked blocks B1 to B6, the operations of steps 1 to 15 in FIG. 4 are repeated.

As described above, in the substrate processing apparatus according to the comparative embodiment in which the auxiliary facilities (the gas box 81, the APC valve 83, and the power supply box 82) are shared by the six vacuum processing modules 4A and 4B, film formation on the wafers W may not be started unless the wafers W are carried into all the vacuum containers 40 of “a-1 to a-3, b-1 to b-3.” Therefore, even after the wafers W are carried into the first vacuum processing module 4A side, a waiting time occurs until the film formation starts (shaded columns on the first vacuum processing module 4A side in steps 4 to 7 in FIG. 4).

In addition, even in carrying out the film-formed wafers W, a relatively long waiting time occurs from the start of the carry-out of the first vacuum processing module 4A on one side to the start of the carry-out of the second vacuum processing module 4B on the other side (shaded columns on the second vacuum processing module 4B side in steps 9 to 12 in FIG. 4).

Due to the influence of the waiting time, in the substrate processing apparatus according to the comparative embodiment, 15 steps are required for processing six wafers W using six vacuum processing modules 4A and 4B (see FIG. 4).

Further, even when cleaning the interior of the vacuum containers 40 by supplying a cleaning gas to the vacuum containers 40, cleaning may not be started unless the wafers W are carried out from all the vacuum containers 40.

In this regard, when using the first substrate conveyance mechanism 2 configured to hold wafers W in multiple tiers in the housing, in the carry-out operation of the wafers W after the film formation in steps 11 and 15 in FIG. 4, the wafers W before the film formation may be received from the first substrate conveyance mechanism 2 to exchange the carried-out wafers W. In this case, in the film formation for the second time or the later, the processing of the wafers W may be performed by the operations of the steps 6 to 15. However, the film formation may still not be started unless the wafers W are carried into all the vacuum containers 40.

In addition, when a placement region for temporarily placing the wafers W is provided in the load lock chamber 32 of the LLM 3, the interior of the LLM 3 may be switched between normal pressure atmosphere and vacuum atmosphere. In this case, it is unnecessary to wait for completion of the carry-in/out operation of the first wafer W. Thus, it is possible to reduce the time required for processing the wafer W using the six vacuum processing modules 4A and 4B.

However, each processing unit U needs to be provided with the LLM 3 having a special configuration having the temporary placement region of the wafer W, and the second substrate conveyance mechanism 33 capable of performing a complicated operation of conveying two wafers W between the first substrate conveyance mechanism 2 or the temporary placement region and each vacuum container 40 of the first and second vacuum processing modules 4A and 4B. Thus, the cost of the apparatus may be increased.

Therefore, similarly to the substrate processing apparatus according to the comparative embodiment, the substrate processing apparatus according to the present embodiment is configured to be able to alleviate restrictions imposed at the time of the carry-in/out of the wafers W while sharing the auxiliary facilities (e.g., the gas box 81, the APC valve 83, and the power supply box 82) in, for example, six vacuum processing modules 4A and 4B.

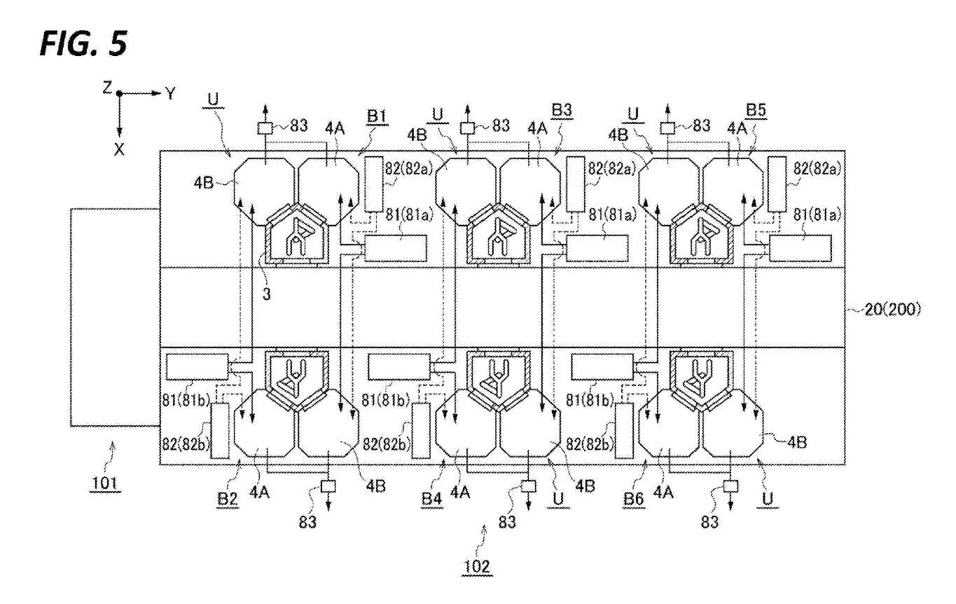

Hereinafter, description will be made on the installation state of the auxiliary facilities in the actual form and the operation of the substrate processing apparatus with reference to FIGS. 5 to 7. Here, in addition to the identification codes for the first vacuum processing modules 4A and the second vacuum processing modules 4B of the stacked block B1 described above, in FIG. 6, the first vacuum processing modules 4A of the stacked block B2 are denoted by identification codes “c-1, c-2, c-3” sequentially from the upper tier side, and the second vacuum processing modules 4B are denoted by identification codes “d-1, d-2, d-3” sequentially from the upper tier side.

As illustrated in FIGS. 5 and 6, the substrate processing apparatus according to the present embodiment has a configuration in which the first vacuum processing modules 4A and the second vacuum processing modules 4B of the processing units U provided in each of the stacked blocks B1 to B6 use different auxiliary facilities (gas boxes 81a and 81b and the power supply boxes 82a and 82b in the present example) to perform film formation on the wafers W.

For example, in the example of the substrate processing apparatus illustrated in FIG. 5, in each processing unit U in the stacked block B1, the first vacuum processing module 4A performs supply of the processing gas and power from the gas box 81a and power supply box 82a, respectively, disposed adjacent to the stacked block B1. Meanwhile, the second vacuum processing module 4B provided in the same processing unit U performs supply of the processing gas and power from the gas box 81b and the power supply box 82b disposed adjacent to the stacked block B2 that faces the stacked block B1 across the substrate conveyance chamber 200.

More specifically, referring to FIG. 6, the gas box 81a and the power supply box 82a supply a processing gas and a power to “a-1 to a-3” which are the first vacuum processing modules 4A of the stacked block B1 and “d-1 to d-3” which are the second vacuum processing modules 4B of the stacked block B2 (illustrated as “group ad” in FIG. 7). In addition, the gas box 81b and the power supply box 82b supply a processing gas and a power to “b-1 to b-3” which are the second vacuum processing modules 4B of the stacked block B1 and “c-1 to c-3” which are the first vacuum processing modules 4A of the stacked block B2 (illustrated as “group bc” in FIG. 7).

Meanwhile, the fact that the APC valve 83 is shared by the first and second vacuum processing modules 4A and 4B in the respective stacked blocks B1 and B 2 via the exhaust pipes 51A and MB as described with reference to FIG. 2 is the same as in the substrate processing apparatus according to the comparative embodiment.

FIG. 6 illustrates an example of the stacked blocks B1 and B2. Similarly, however, for the other stacked blocks B3 to B6, the gas box 81a and the power supply box 82a are shared in the first vacuum processing modules 4A of the stacked blocks B3 and B5 that face each other across the substrate conveyance chamber 200 and the second vacuum processing modules 4B of the stacked blocks B4 and B6. In addition, the gas box 81b and the power supply box 82b are shared in the second vacuum processing modules 4B of the stacked blocks B3 and B5 and the first vacuum processing modules 4A of the stacked blocks B4 and B6 (FIG. 5).

Meanwhile, for the APC valve 83, the APC valve 83 is shared between the first vacuum processing module 4A and the second vacuum processing module 4B in each of the stacked blocks B3 to B6.

To explain the configuration described above in accordance with the description of the claims, the 36 vacuum processing modules 4A and 4B provided in the stacked blocks B1 to B6 are grouped into a first group set including six groups each including six vacuum processing modules 4A and 4B (i.e., three groups each including the first vacuum processing modules 4A of each of the stacked blocks B1, B3, B5 and the second vacuum processing modules 4B of each of the stacked blocks B2, B4, B6, and three groups each including the second vacuum processing modules 4B of each of the stacked blocks B1, B3, B5 and the first vacuum processing modules 4A of each of the stacked blocks B2, B4, B6), and the gas boxes 81 (81a and 81b), the power supply boxes 82 (82a and 82b), which are auxiliary facilities, are shared in each group.

Therefore, when viewed in the stacked blocks B1 to B6, the first vacuum processing modules 4A included in one of the stacked blocks B1 to B6 are grouped into a common group, and the second vacuum processing modules 4B included in the one of the stacked blocks B1 to B6 are grouped into a common group different from the group including the first vacuum processing modules 4A.

Further, the same 36 vacuum processing modules 4A and 4B are grouped into a second group set including six groups each including a combination of six vacuum processing modules 4A and 4B which is different from that of the first and second vacuum processing modules 4A and 4B in each group of the first group set (i.e., six groups each including the first and second vacuum processing modules 4A and 4B in each of the stacked blocks B1 to B6), and the APC valve 83, which is auxiliary facilities, is shared in each group.

Descriptions will be made on a processing operation of the wafers W by the substrate processing apparatus according to the embodiment having the above-described configuration.

The point that wafers W are taken out from the carriers C and the first substrate conveyance mechanism 2 is moved to the arrangement position of the stacked blocks B1 to B6 that accommodate the processing units U that performs film formation on the wafers W from the carrier C is the same as in the case of the substrate processing apparatus according to the comparative embodiment described above. Thus, the description thereof will be omitted. Further, in the present example, descriptions will be made on a case where a wafer W is carried into each processing unit U of the stacked blocks B1 and B2 illustrated in FIGS. 5 and 6.

Also in the substrate processing apparatus according to the embodiment, the operation of carrying a wafer W from the first substrate conveyance mechanism 2 to the LLM 3, switching the interior of the load lock chamber 32 to the vacuum atmosphere, and then, carrying the wafer W in the load lock chamber 32 into the vacuum container 40 is the same as that in the substrate processing apparatus according to the comparative embodiment described with reference to FIG. 4 (steps 1 to 3 in FIG. 7).

Meanwhile, in the above-described carry-in operation of the wafers W, it is different from the substrate processing apparatus according to the comparative example described above in that the wafers W are carried into the vacuum containers 40 of “a-1 to a-3” which are the first vacuum processing modules 4A of the stacked block B1 and the vacuum containers 40 of the stacked block B2 and the vacuum containers 40 of “d-1 to d-3” which are the processing modules 4B.

Since the above-described six vacuum processing modules 4A and 4B are supplied with a processing gas and a power from the common gas box 81a and the power supply box 82a, film formation may be started when the wafers W are carried into the vacuum containers 40 of “a-1 to a-3, d-1 to d-3 (group ad)” (step 4 in FIG. 7). At this time, each APC valve 83 of the stacked blocks B1 and B2 performs pressure adjustment such that the pressure in the vacuum container 40 in which the film formation is performed becomes a target pressure.

Further, in parallel with the start of the film formation in each of the vacuum processing modules 4A and 4B into which the wafer W has been carried, the interior of the LLM 3 is returned to the normal pressure atmosphere (step 4 in FIG. 7). Each step illustrated in FIGS. 4 and 7 does not indicate a uniform time interval, but indicates a measure of the execution timing of each operation. Therefore, the time until the completion of the film formation described in step 8 of FIG. 4 may require time for several steps of other operations performed in parallel with the film formation in FIG. 7 in some cases. Therefore, in FIG. 7, the film formation performed in parallel with other operations is also described as “film formation” together with the waiting time after the completion of the film formation.

Next, in steps 5 to 7 in FIG. 7, the wafers W are carried into the vacuum containers 40 of “b-1 to b-3” which are the second vacuum processing modules 4B of the stacked block B1 and the vacuum containers 40 of “c-1 to c-3” which are the first vacuum processing modules 4A of the stacked block B2. Here, the vacuum containers 40 are supplied with the processing gas and power from the common gas box 81b and power supply box 82b.

When the wafers W are carried into the vacuum containers 40 of “b-1 to b-3, c-1 to c-3 (group bc),” the film formation is started also in these vacuum processing modules 4A and 4B (step 8 in FIG. 7).

At the start of the film formation in the vacuum processing modules 4A and 4B, when the film formation on the side of the vacuum processing modules 4A and 4B in which the processing has been started first has been completed, or even not completed, each APC valve 83 of the stacked blocks B1 and B2 may perform pressure adjustment such that the pressure in the vacuum containers 40 becomes a target pressure at the time of the film formation.

When the film formation on the first vacuum processing modules 4A of the stacked block B1 and the second vacuum processing modules 4B of the stacked block B2 which has been started first in the period of steps 5 to 8 is completed, the wafer W is delivered from each vacuum container 40 of “group ad” to the first substrate conveyance mechanism 2 via the LLM 3 in a procedure opposite to that at the time of the carry-in of the wafers W (steps 9 to 11 in FIG. 7). Further, in step 11, the next wafer W on which film formation is to be performed in each vacuum container 40 of “group ad” is carried into the LLM 3 in order to replace the wafer W carried out after the film formation.

Next, after the interior of the load lock chamber 32 of each LLM 3 is switched to a vacuum atmosphere (step 12), the wafer W in the LLM 3 is carried into the vacuum container 40 of “group ad” (step 13). Further, at this time, when the film formation on the second vacuum processing modules 4B of the stacked block B1 and the first vacuum processing modules 4A of the stacked block B2 which has been started later in the period of steps 9 to 12 is completed, the film-formed wafer W is carried out from each vacuum container 40 of “group bc” to the LLM 3 (step 13). When the film formation on the “group bc” side has not completed at the end of step 12, the wafer W is carried out after waiting for the completion of the film formation (step 13).

Thereafter, in each vacuum container 40 of “group ad,” the film formation for the next wafer W is started (step 14). In parallel with the start of the film formation, the LLM 3 which has received the wafer W subjected to the film formation in each vacuum container 40 of “group bc” switches the interior of the load lock chamber 32 from the vacuum atmosphere to the normal pressure atmosphere (step 14). Then, the wafer W is delivered to the first substrate conveyance mechanism 2 (step 15). Further, in step 15, the next wafer W on which film formation is to be performed in each vacuum container 40 of “group bc” is carried into the LLM 3 in order to replace the wafer W carried out after the film formation.

Next, after the interior of the load lock chamber 32 of each LLM 3 is switched to a vacuum atmosphere (step 16), the wafer W in the LLM 3 is carried into the vacuum container 40 of “group bc” (step 17). Further, at this time, when the film formation on the first vacuum processing modules 4A of the stacked block B1 and the second vacuum processing modules 4B of the stacked block B2 in the period of steps 14 to 16 is completed, the film-formed wafer W is carried out from each vacuum container 40 of “group ad” to the LLM 3 (step 17). When the film formation on the “group ad” side has not completed at the end of step 16, the wafer W is carried out after waiting for the completion of the film formation (step 17).

Thereafter, in each vacuum container 40 of “group bc,” the film formation for the next wafer W is started (step 18). In parallel with the start of the film formation, the LLM 3 which has received the wafer W subjected to the film formation in each vacuum container 40 of “group ad” switches the interior of the load lock chamber 32 from the vacuum atmosphere to the normal pressure atmosphere (step 18).

Thereafter, by repeating the operation illustrated in steps 11 to 18 in FIG. 7, the film formation may be alternately performed in the vacuum containers 40 of “group ad” and the vacuum containers 40 of “group bc.”

Also in the processing units U provided in the stacked blocks B3 and B4 and the stacked blocks B5 and B6, the operation described with reference to FIG. 7 is executed.

As described above, in the substrate processing apparatus described with reference to FIGS. 5 and 7, the gas box 81a and the power supply box 82a are shared in the first vacuum processing modules 4A of the stacked blocks B1, B3, and B5 and the second vacuum processing modules 4B of the stacked blocks B2, B4, and B6 which face each other across the substrate conveyance chamber 200, and the gas box 81b and the power supply box 82b are shared in the second vacuum processing modules 4B of the stacked blocks B1, B3, B5 and the first vacuum processing modules 4A of the stacked blocks B2, B4, and B6.

As a result, for example, when attention is paid to the stacked blocks B1 and B2 illustrated in FIG. 6, even though the wafers W are not carried into all the vacuum containers 40 of the stacked blocks B1 and B2, the film formation may be started at the stage where the wafers W are carried into the six vacuum containers 40 (group ad: a-1 to a-3, d-1 to d-3) which are supplied with a processing gas and a power from the gas box 81a and the power supply box 82a, respectively.

In addition, with respect to the remaining six vacuum containers 40 (group bc: b-1 to b-3, c-1 to c-3) which supplied with a processing gas and a power from the gas box 81b and the power supply box 82b, since the carry-in of the wafers W may be performed concurrently with the film formation on group ad side, it is possible to reduce the waiting time until the film formation is started.

As a result, in the second or subsequent film formation after the first film formation in each group (group ad and group bc), twelve wafers W may be subjected to film formation in eight steps (steps 11 to 18 in FIG. 7) using twelve vacuum processing modules 4A and 4B.

As described above, the respective steps illustrated in FIGS. 4 and 7 do not indicate uniform time intervals, but it is possible to securely reduce the waiting time caused by the fact that the film formation may be started only after the wafers W have been carried into all of the vacuum containers 40 by the substrate processing apparatus according to the comparative embodiment.

Here, with respect to the respective stacked blocks B1 to B6, the method of grouping the first vacuum processing modules 4A included in one of the stacked blocks B1 to B6 into a common group, and grouping the second vacuum processing modules 4B included in the one of the stacked blocks B1 to B6 into a common group different from the group including the first vacuum processing modules 4A, is not limited to the example illustrated in FIG. 5.

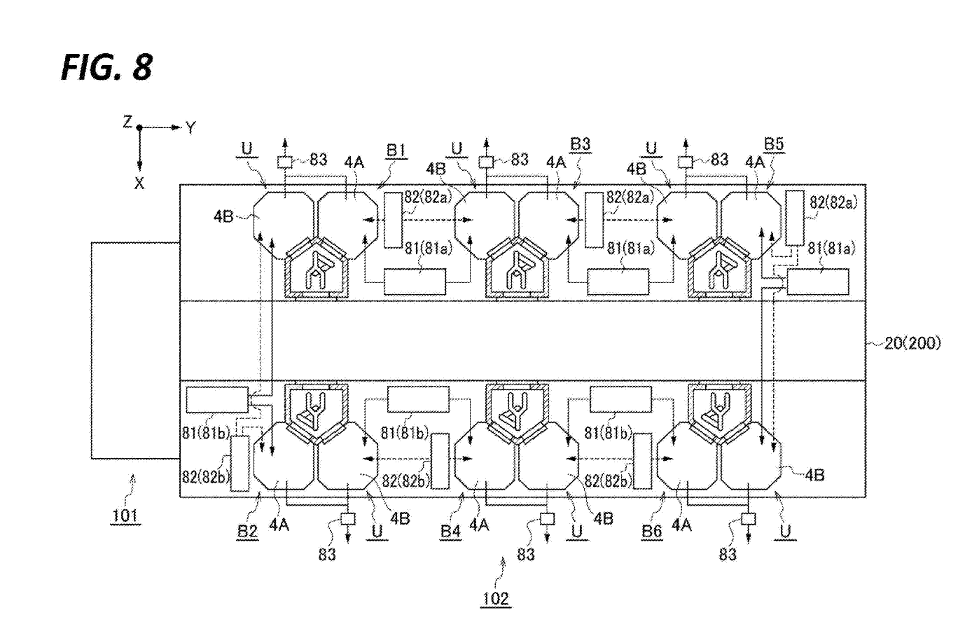

For example, in the example illustrated in FIG. 8, only with respect to the second vacuum processing module 4B of the stacked block B1 and the first vacuum processing module 4A of the stacked block B2 which are the nearest to the EFEM 101 side, and the first vacuum processing module 4A of the stacked block B5 and the second vacuum processing module 4B of the stacked block B6 which are the farthest therefrom, the gas boxes 81a and 81b and the power supply boxes 82a and 82b are shared by the first vacuum processing module 4A and the second vacuum processing module 4B, which are disposed to face each other across the substrate conveyance chamber 200. With respect to the remaining vacuum processing modules 4A and 4B, the gas boxes 81a and 81b and the power supply boxes 82a and 82b are shared by the first vacuum processing module 4A and the second vacuum processing module 4B of the adjacent stacked blocks B1, B3, B5, B2, B4, and B6.

Further, in order to implement the processing procedure of the wafers W described with reference to FIG. 7, at least for the gas boxes 81, the film formation may be performed using different gas boxes 81a and 81b in the first vacuum processing modules 4A and the second vacuum processing modules 4B of the processing units U provided in each of the stacked blocks B1 to B6. For example, vacuum processing modules 4A and 4B which are provided with a heating unit and are not provided with a plasma generation unit are shared by every six vacuum processing modules 4A and 4B in each of the stacked blocks B1 to B6. Then, as in the case of the APC valve 83, the temperature adjustment may be performed such that the temperature of the wafers W in the vacuum containers 40 in which the film formation is performed becomes the target temperature.

Referring to FIGS. 1 to 5, it has been described that when a plurality of vacuum processing modules 4A and 4B are distributed into a plurality of group sets (first and second group sets) which are grouped differently from each other to share auxiliary facilities (e.g., the gas box 81, the power supply box 82, and the APC valve 83), it is possible to reduce restrictions (waiting time) caused when the wafers W are carried into and from the vacuum processing modules 4A and 4B.

Here, the restrictions that may be reduced by adopting the above configuration are not limited to the waiting time caused by the conveyance operation of the wafers W. For example, in the above-described substrate processing apparatus according to the comparative embodiment, it is also possible to alleviate restrictions related to the setting of processing conditions occurring when processing the wafers W in the vacuum processing modules 4A and 4B.

In the substrate processing apparatus according to the comparative embodiment illustrated in FIG. 3, the gas box 81, the APC valve 83, and the power supply box 82 which are auxiliary facilities are shared by all the vacuum processing modules 4A and 4B in any one of the stacked blocks B1 to B6.

As described above, the gas box 81 is provided with an MFC 812 which is a processing gas adjustment unit for adjusting the supply flow rate of the processing gas and an opening/closing valve V which is a processing gas adjustment unit for adjusting the execution timing of the supply of the processing gas and the stop of the supply. Therefore, the MFC 812 and the opening/closing valve V perform common flow rate adjustment and supply timing adjustment for all the vacuum processing modules 4A and 4B that share the gas box 81.

This also applies to other auxiliary facilities. Also for the adjustment of the pressure inside the vacuum container 40 by the APC valve 83 which is a pressure adjustment unit and the adjustment of the power supply amount to the plasma generation unit and the heating unit by the power supply unit 821 in the power supply box 82 which is the power supply control unit, common adjustment is performed for all the vacuum processing modules 4A and 4B that share the APC valve 83 and the power supply box 82.

Meanwhile, in the substrate processing apparatus having a plurality of vacuum processing modules 4A and 4B, even though film formation is performed under the same processing conditions, a machine difference in which the processing result (e.g., film thickness) is slightly different may occur for each of the vacuum processing modules 4A and 4B.

In this regard, in a single wafer processing apparatus capable of changing processing conditions for individual vacuum processing modules, it is possible to make individual settings such as, for example, “increase the film formation time by +0.2 seconds,” or “reduce the flow rate of the processing gas by +0.1 sccm.”

However, in the substrate processing apparatus according to the comparative example in which the auxiliary facilities having various adjustment functions are shared, it is not possible to set individual processing conditions for each of the vacuum processing modules 4A and 4B included in each of the stacked blocks B1 to B6.

Meanwhile, similarly to the single wafer processing apparatus, providing individual processing gas adjustment units, pressure adjustment units, and power supply adjustment units for all of the vacuum processing modules 4A and 4B in the substrate processing apparatus is a factor causing a drastic increase in apparatus cost and an increase in size of the apparatus.

Therefore, in a substrate processing apparatus according to a second embodiment, a plurality of vacuum processing modules 4A and 4B are distributed into a plurality of group sets (first to third group sets) which are grouped differently from each other to share auxiliary facilities (e.g., the gas box 81, the power supply box 82, and the APC valve 83), so that the restriction on setting of the processing conditions is alleviated.

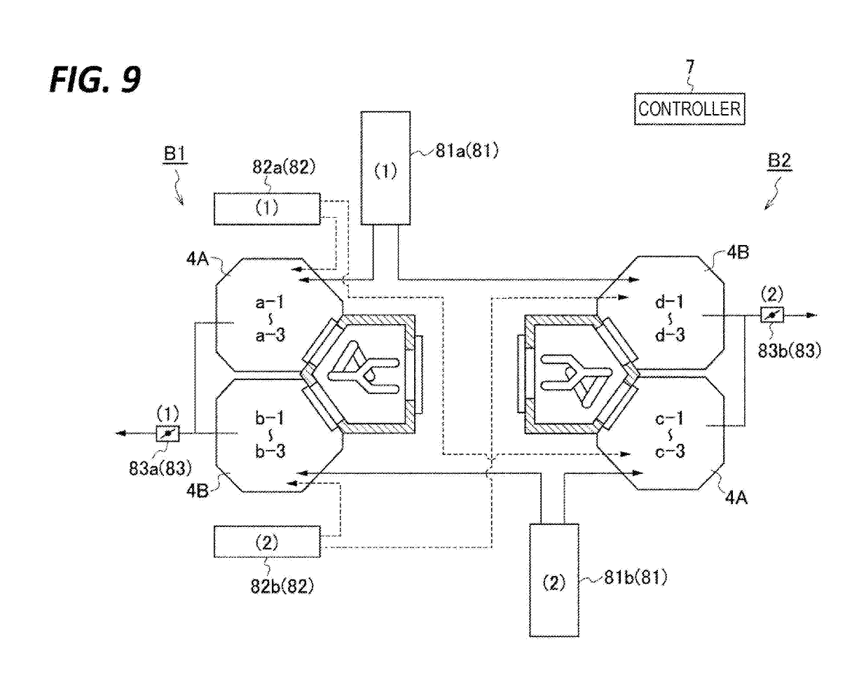

Hereinafter, the substrate processing apparatus according to the second embodiment will be described with reference to FIGS. 9 and 11. In FIG. 9, components common to those in the substrate processing apparatus according to the first embodiment described with reference to FIGS. 1 and 2 are denoted by the same reference numerals as used in these figures.

The substrate processing apparatus according to the second embodiment has the same configuration as that of the substrate processing apparatus described with reference to FIGS. 1 and 2. FIG. 9 illustrates the stacked blocks B1 and B2 and the auxiliary facilities thereof in the substrate processing apparatus in order to depict the technical features of the embodiment in an easy-to-understand manner.

The substrate processing apparatus including the twelve vacuum processing modules 4A and 4B illustrated in FIG. 9 are grouped into a first group set including two groups each including six vacuum processing modules 4A and 4B (i.e., a group including the first vacuum processing modules 4A of the stacked block B1 and the second vacuum processing modules 4B of the stacked block B2, and a group including the second vacuum processing modules 4B of the stacked block B1 and the first vacuum processing modules 4A of the stacked block B2), and the gas boxes 81 (81a and 81b) selected from the auxiliary facility group (e.g., the gas box 81, the power supply box 82, and the APC valve 83) are shared in each group in the first group set. Further, in the following descriptions of FIGS. 9 to 11, different conditions set for each auxiliary facility (e.g., gas boxes 81a and 81b, APC valves 83a and 83b, and power supply boxes 82a and 82b) are identified using the codes “(1) and (2).”

The gas boxes 81a and 81b may set different conditions “(1) and (2)” for the supply flow rate of the processing gas and the supply/stop timing of the processing gas.

Further, the twelve vacuum processing modules 4A and 4B are grouped into a second group set including two groups each including a combination of six vacuum processing modules 4A and 4B which is different from that of the vacuum processing modules 4A and 4B in each group in the first group set (i.e., two groups each including the first and second vacuum processing modules 4A and 4B in each of the stacked blocks B1 to B6), and the APC valves 83 (83a and 83b) selected from the auxiliary facility group are shared in each group in the second group set.

The APC valves 83a and 81b may set different conditions “(1) and (2)” for the pressure in the vacuum containers 40.

Further, the same twelve vacuum processing modules 4A and 4B are grouped into a third group set including two groups each including a combination of six vacuum processing modules 4A and 4B which is different from those of the vacuum processing modules 4A and 4B in each group of the first and second group sets (i.e., a group including the first vacuum processing modules 4A of the stacked block B1 and the first vacuum processing modules 4A of the stacked block B2, and a group including the second vacuum processing modules 4B of the stacked block B1 and the second vacuum processing modules 4B of the stacked block B2), and the power supply boxes 82 (82a and 82b) selected from the auxiliary facility group are shared in each group in the third group set.

The power supply boxes 82a and 82b may set different conditions “(1) and (2)” for the power supply amount to the plasma generation units or heating units.

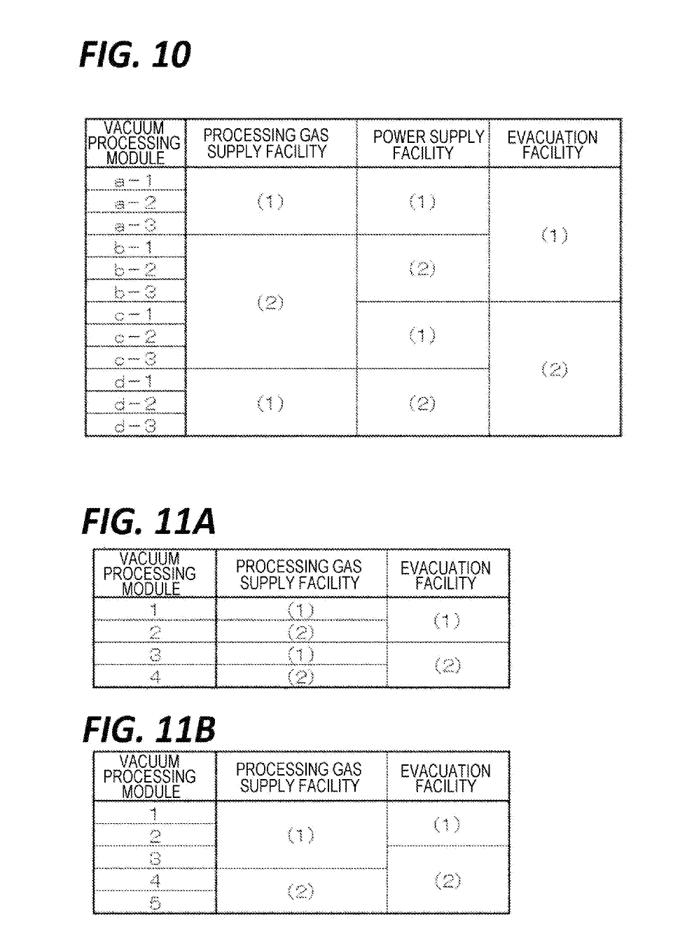

FIG. 10 is a table summarizing process conditions that may be set for each of the vacuum processing modules 4A and 4B in the substrate processing apparatus illustrated in FIG. 9.

According to FIG. 10, the twelve vacuum processing modules 4A and 4B are configured such that each of the groups “a-1 to a-3,” “b-1 to b-3,” “c-1 to c-3,” and “d-1 to d-3” share a different combination of auxiliary facilities (the gas boxes 81a and 81b, the power supply boxes 82a and 82b, and the APC valves 83a and 83b).

As a result, for example, for the first vacuum processing module 4A of “a-1 to a-3,” the processing condition (1) of the gas box 81a, the processing condition (1) of the power supply box 82a, and the processing condition (1) of the APC valve 83a are set. For the second vacuum processing module 4B of “b-1 to b-3,” it is possible to set the processing condition (2) of the gas box 81b, the processing condition (2) of the power supply box 82b, and the processing condition (1) of the APC valve 83a, which are different from the combination of processing conditions for “a-1 to a-3.”

This also applies to the other vacuum processing modules 4A and 4B related to “c-1 to c-3 and d-1 to d-3,” and combinations of different processing conditions may be set.

For example, as for the relationship between the processing condition of the wafer W and the film thickness of the formed film, it is assumed that the film thickness tends to become thicker as the film formation time adjusted according to the supply/stop timing of the processing gas increases or as the supply flow rate of the processing gas increases, and the film thickness tends to become thinner when the opposite adjustment is performed. In addition, as for the other processing conditions, it is assumed that the film thickness tends to become thicker as the pressure in the vacuum container 40 increases, or as the power supply amount to the heating unit increases so that the heating temperature of the wafer W increases or the degree of ionization of the plasma increases, and the film thickness tends to become thinner when the opposite adjustment is performed.

At this time, with respect to each of the vacuum processing modules 4A and 4B illustrated in FIG. 9, the above-described relationship between the processing conditions and the film thickness is grasped by, for example, preliminary experiments to grasp individual machine differences. Further, a correlation of the processing conditions that may offset the machine difference of each group unit (relational expression) may be determined by determining the relationship between the processing conditions and the average film thickness for each of the groups (“a-1 to a-3,” “b-1 to b-3,” “c-1 to c-3,” and “d-1 to d-3”) of the vacuum processing modules 4A and 4B that may change the combination of the processing conditions.

Then, the result of the film formation on the wafer W may be made more uniform between the respective groups by determining a combination of the processing conditions that minimize the machine difference of each group using, for example, a linear programming method (by setting a target value of each adjustment unit). The combination of the processing conditions is calculated and set by the controller 7, for example, when setting a processing recipe of the wafer W.

According to the embodiment described with reference to FIGS. 9 and 10, a plurality of vacuum processing modules 4A and 4B are distributed into a plurality of group sets (first to third group sets) that are grouped differently from each other to share the auxiliary facilities (e.g., the gas boxes 81a and 81b, the power supply boxes 82a and 82b, and the APC valves 83a and 83b). Thus, it is possible to set combinations of different processing conditions among the vacuum processing modules 4A and 4B which differ in combination of the auxiliary facilities to be shared.

According to the embodiment described with reference to FIGS. 9 and 10, a plurality of vacuum processing modules 4A and 4B are distributed into a plurality of group sets (first to third group sets) that are grouped differently from each other to share the auxiliary facilities (e.g., the gas boxes 81a and 81b, the power supply boxes 82a and 82b, and the APC valves 83a and 83b). Thus, it is possible to set combinations of different processing conditions among the vacuum processing modules 4A and 4B which differ in combination of the auxiliary facilities to be shared.

However, the minimum number of the vacuum processing modules 4A and 4B to which this embodiment is applicable, and the number of types of auxiliary facilities are not limited to the example described with reference to FIGS. 9 and 10. The present disclosure may be applied as long as the substrate processing apparatus is provided with at least four vacuum processing modules 4 and at least two types of auxiliary facilities.

For example, FIG. 11A illustrates an example in which two types of auxiliary facilities (for example, the gas boxes 81a and 81b and the APC valves 83a and 83b) are distributed into two group sets with respect to four vacuum processing modules denoted as “1, 2, 3, and 4.”

As a result, it is possible to set four types of combinations of processing conditions among different vacuum processing modules “1, 2, 3, and 4.”

Further, in the groups constituting each group set, at least one vacuum processing module in the combination of the vacuum processing modules included in each group may be different. In the example illustrated in FIG. 11B, with respect to five vacuum processing modules denoted as “1, 2, 3, 4, and 5,” the gas boxes 81a and 81b are distributed into a group denoted as “1, 2, and 3” and a group denoted as “4 and 5,” and the APC valves 83a and 83b are distributed into a group denoted as “1 and 2” and a group denoted as “3, 4, and 5.”

In this example, it is possible to set three kinds of combinations of processing conditions among different vacuum processing modules “1, 2, 3, 4, and 5.”

Descriptions will be made by generalizing the above-described method. When there is a substrate processing apparatus including n processing modules (n is an integer of 4 or more, n=36 in the example of FIG. 1), the n vacuum processing modules 4A and 4B are grouped into a first group set including a plurality of groups each including 2 to (n−2) vacuum processing modules 4A and 4B. Then, the vacuum processing modules 4A and 4B included in each group share at least one first auxiliary facility selected from the auxiliary facility group (e.g., the gas box 81).

Further, the n vacuum processing modules 4A and 4B are grouped into a second group set including a plurality of groups each including 2 to (n−2) vacuum processing modules 4A and 4B. Each group includes a combination of vacuum processing modules 4A and 4B in which at least one vacuum processing module is different from the combination of vacuum processing modules included in each group of the first group set. Then, the vacuum processing modules 4A and 4B included in each group share at least one second auxiliary facility (e.g., the power supply box 82) selected from the auxiliary facility group and different from the first auxiliary facility.

At this time, it is assumed that auxiliary facilities remaining unselected as the first and second auxiliary facilities (for example, the above-mentioned APC valve 83 and a chiller facility that controls the temperature of the vacuum container 40 by supplying a coolant to a coolant flow path formed in the vacuum container 40 or a member constituting the placing table) remain in the auxiliary facility group. In this case, the n vacuum processing modules 4A and 4B may be grouped into an i^{th} group set including a plurality of groups each including 2 to (n−2) vacuum processing modules 4A and 4B. Each group includes a combination of vacuum processing modules 4A and 4B in which at least one vacuum processing module is different from the combinations of vacuum processing modules included in each group of the first to (i−1)^{th} group sets. Then, the vacuum processing modules 4A and 4B included in each group may share at least one second auxiliary facility (e.g., one of the APC valve 83 and the chiller facility) selected from the auxiliary facility group and different from the first to (i−1)^{th} auxiliary facilities. Here, i is an integer of 3 to a value obtained by adding to a value of (i−1) the number of facilities in the auxiliary facility group which are not selected up to the (i−1)^{th} group set.

According to the example described above, both the APC valve 83 and the chiller facility may be shared by the vacuum processing modules 4A and 4B included in each group of the common third group set (i=3).

Further, it is assumed that either side of the APC valve 83 and the chiller facility is shared by each group of the third group set. At this time, the n vacuum processing modules 4A and 4B may be further grouped into a fourth group set (i=4), and the remaining auxiliary facility (the APC valve 83 or the chiller facility) on the other side may be shared in each group of the fourth group set.

According to the concept described above, the example illustrated in FIGS. 9 and 10 corresponds to the case of i=3. Further, the number of types of auxiliary facilities included in the auxiliary facility group is not limited to three, and may be, for example, four or more.

Examples of the auxiliary facilities that may be included in the auxiliary facility group include the above-described chiller facility in addition to the gas box 81, the power supply box 82, and the APC valve 83. The chiller facility performs temperature adjustment of the vacuum container 40 by using a temperature control unit that adjusts at least one of the temperature or the flow rate of the coolant supplied to the coolant flow path formed on the vacuum container 40 or the placing table of the wafer W.

In addition, it is not indispensable to share all the auxiliary facilities provided in the substrate processing apparatus by the plurality of vacuum processing modules 4A and 4B. As described above, at least two types of auxiliary facilities may be shared, and the remaining auxiliary facilities may be individually provided in the vacuum processing modules 4A and 4B.

Further, the substrate processing apparatus to which the present disclosure is applicable is not limited to one having the stacked blocks B1 to B6 configured by stacking the processing units U, to which the first and second vacuum processing modules 4A and 4B are connected, in multiple tiers in the vertical direction in the LLM 3, as described, for example, with reference to FIGS. 1 and 2.

For example, the present disclosure may also be applied to a multi-chamber type substrate processing apparatus in which four or more vacuum processing modules are connected to a side wall surface of a vacuum conveyance chamber into which a wafer W is conveyed under a vacuum atmosphere.

In addition, the types of processings performed by the vacuum processing modules 4A and 4B of the processing unit U provided in the substrate processing apparatus are not limited to the film formation, and may be, for example, etching, ashing, or annealing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
n (n is an integer of 4 or more) vacuum processing modules each provided with a vacuum container for processing a substrate in a vacuum atmosphere; and
an auxiliary facility group including a processing gas supply facility that supplies a processing gas into the vacuum container, an evacuation facility that evacuates the vacuum container, a chiller facility that controls a temperature of the vacuum container, and a power supply facility that supplies a power to power consuming devices provided in the vacuum processing modules;
wherein the n vacuum processing modules are grouped into a first group set including a plurality of groups each including a combination of 2 to (n−2) vacuum processing modules, and the vacuum processing modules included in each group share at least one first auxiliary facility selected from the auxiliary facility group, and
the n vacuum processing modules are grouped into a second group set including a plurality of groups each including a combination of 2 to (n−2) vacuum processing modules in which at least one vacuum processing module is different from the combination of vacuum processing modules included in each group of the first group set, and the vacuum processing modules included in each group share at least one second auxiliary facility selected from the auxiliary facility group and different from the first auxiliary facility.

2. The substrate processing apparatus of claim 1, further comprising:
a substrate conveyance section provided with a first substrate conveyance mechanism that conveys the substrate under a normal pressure atmosphere,
wherein the n vacuum processing modules are separately provided in a plurality of processing units each including first and second vacuum processing modules, and a load lock module that is connected to each of the vacuum containers of the first and second vacuum processing modules and provided with a second substrate conveyance mechanism that conveys the substrate between the substrate conveyance section and each of the vacuum containers in a load lock chamber configured to freely switch an internal atmosphere between a normal pressure atmosphere and a vacuum atmosphere, and
the first auxiliary facility includes a gas supply facility, and the first and second vacuum processing modules in each of the processing units are grouped into different groups in the first group set.

3. The substrate processing apparatus of claim 2, wherein the plurality of processing units are stacked vertically in multiple tiers to form a plurality of stacked blocks, and
for each of the plurality of stacked blocks, the first vacuum processing modules included in one stacked block are grouped into a common group, and the second vacuum processing modules included in the stacked block are grouped into a common group different from the group including the first vacuum processing modules.

4. The substrate processing apparatus of claim 3, wherein the first and second vacuum processing modules in each of the processing units are arranged side by side in a lateral (left and right) direction when viewed from the load lock module side, the first vacuum processing modules are evenly stacked vertically in multiple tiers on one side of the left and right sides, and the second vacuum processing modules are evenly stacked vertically in multiple tiers on the other side of the left and right sides,
the substrate conveyance section is constituted by disposing the first substrate conveyance mechanism in an elongated planar substrate conveyance chamber, and on both sides of the substrate conveyance section, the plurality of stacked blocks are arranged side by side along a longer side direction of the elongated substrate conveyance chamber, and
for two stacked blocks adjacent to each other along the substrate conveyance chamber or two stacked blocks facing each other across the substrate conveyance chamber, first vacuum processing modules of one stacked block and second vacuum processing modules of the other stacked block are grouped into a common group.

5. The substrate processing apparatus of claim 1, wherein when facilities remaining unselected as the first and second auxiliary facilities remain in the auxiliary facility group,
the n vacuum processing modules are further grouped into an i-th group set including a plurality of groups each including a combination of 2 to (n−2) vacuum processing modules in which at least one vacuum processing module is different from the combination of vacuum processing modules included in each group of the first to (i−1)^{th} group sets, and the vacuum processing modules included in each group share at least one i^{th} auxiliary facility selected from the auxiliary facility group and different from the first to (i−1)^{th} auxiliary facilities (i is an integer of 3 to a value obtained by adding to a value of (i−1) a number of facilities in the auxiliary facility group which are not selected up to the (i−1)^{th} group set).

6. The substrate processing apparatus of claim 1, wherein the processing gas supply facility includes a processing gas adjustment unit that performs at least one of adjustment of execution timing of supply of a processing gas into the vacuum container or stop of the supply and adjustment of supply flow rate of the processing gas, the evacuation facility includes a pressure adjustment unit that adjusts a pressure in the vacuum container, the power supply facility includes a power supply unit that adjusts a power to be supplied to at least one of a plasma generation unit configured to convert the processing gas supplied into the vacuum container into plasma and a heating unit configured to heat the substrate disposed in the vacuum container, and the chiller facility includes a temperature adjustment unit that adjusts at least one of a temperature and a flow rate of a coolant to be supplied to a coolant flow path formed in the vacuum container or a placing table of the substrate.

7. The substrate processing apparatus of claim 6, further comprising:
a controller that sets a target value of each adjustment unit provided in the auxiliary facilities such that results of the processing on the substrate become uniform among vacuum processing modules having different combinations of shared auxiliary facilities.
